(19) United States
(12) Patent Application Publication
(10) Pub. No.: US 2015/0049445 A1
(43) Pub. Date: Feb. 19, 2015

(54) METHOD FOR MANUFACTURING ELECTRONIC COMPONENT EMBEDDING SUBSTRATE AND ELECTRONIC COMPONENT EMBEDDING SUBSTRATE

(71) Applicant: Samsung Electro-Mechanics Co., Ltd., Suwon (KR)

(72) Inventors: Hong Won KIM, Suwon (KR); Seok Kyu Lee, Yeongi (KR); Tae Gon Lee, Daejeon (KR); Byung Hak Kang, Daejeon (KR); Jung Soo Byun, Anyang (KR); Yeon Seop Yu, Sungnam (KR); Sang Mi Yoon, Yeongi (KR)

(73) Assignee: Samsung Electro-Mechanics Co., Ltd., Suwon (KR)

(21) Appl. No.: 14/156,837

(22) Filed: Jan. 16, 2014

(30) Foreign Application Priority Data
Aug. 14, 2013 (KR) 10-2013-0096648

(51) Int. Cl. H05K 1/02; H05K 3/30; H05K 1/18

(52) U.S. Cl. CPC H05K 1/0271; H05K 1/185; H05K 3/30; H05K 2201/10431; H05K 2201/068
USPC 361/761; 361/748; 29/832

(57) ABSTRACT

Disclosed herein are a method for manufacturing an electronic component embedding substrate and an electronic component embedding substrate. The method for manufacturing an electronic component embedding substrate includes: inserting an electronic component into a cavity formed in a core substrate; stacking a first insulating layer on one side of the core substrate into which the electronic component is inserted; performing surface treatment on the other side of the core substrate opposite to a direction in which the first insulating layer is stacked to improve a surface roughness of at least an exposed surface of the first insulating layer; and stacking a second insulating layer on the other side of the core substrate so as to be bonded to the exposed surface of the first insulating layer of which the surface roughness is improved. In addition, disclosed herein is the electronic component embedding substrate.

### CROSS REFERENCE(S) TO RELATED APPLICATIONS

This application claims the foreign priority benefit under 35 U.S.C. Section 119 of Korean Patent Application Serial No. 10-2013-0096648, entitled “Method for Manufacturing Electronic Component Embedding Substrate and Electronic Component Embedding Substrate” filed on Aug. 14, 2013, which is hereby incorporated by reference in its entirety into this application.

### BACKGROUND OF THE INVENTION

1. Technical Field

The present invention relates to a method for manufacturing an electronic component embedding substrate and an electronic component embedding substrate.

2. Description of the Related Art

In accordance with development of an electronic industry, the demand for multi-functionalization and miniaturization of an electronic component has increased. Particularly, in accordance with thinness and lightness of a personal portable terminal, a printed circuit board tends to be thinned and become light, and an effort to provide more functions in a limited area has been continuously conducted. Therefore, one of the next generation multi-functional and small package technologies, an electronic component embedding substrate has been spotlighted.

Describing in a scheme according to the related art in which an electronic component is embedded, a cavity in which the electronic component is to be mounted is formed in a substrate on which a core layer circuit is formed, and a lower end of the cavity is taped, and the electronic component is embedded in the cavity. Build-up layers are sequentially formed on upper and lower layers of the cavity and are electrically connected to a pad of the electronic component through vias to manufacture the electronic component embedding substrate.

In this case, when the electronic component embedding substrate is manufactured by mounting the electronic component in the cavity and applying a sequential stacking scheme, that is, a scheme in which an insulating resin is primarily stacked on one surface and is secondarily stacked on the other surface as in the related scheme, since the sequentially stacked insulating resins are not simultaneously formed, bonding force between a surface of the primarily stacked insulating resin and a surface of the secondarily stacked insulating layer is relatively weak.

In the case of a low CTE (Coefficient of Thermal Expansion) resin, an amount of filler is further increased, such that bonding force of the resin is relatively low, thereby causing delamination on an interface between the primarily stacked insulating resin and the secondary stacked insulating resin.

### RELATED ART DOCUMENT

### Patent Document

(Patent Document 1) Korean Patent Laid-Open Publication No. 10-2001-0092431 (published on Oct. 24, 2001)

### SUMMARY OF THE INVENTION

An object of the present invention is to provide a method for manufacturing an electronic component embedding substrate and an electronic component embedding substrate that are capable of improving bonding force on a bonding interface by primarily stacking a first insulating material, performing surface treatment on a surface of the first insulating material forming the bonding interface together with a second insulating material to improve a surface roughness, and secondarily stacking a second insulating material.

According to an exemplary embodiment of the present invention, there is provided a method for manufacturing an electronic component embedding substrate, the method including: inserting an electronic component into a cavity formed in a core substrate; stacking a first insulating layer on one side of the core substrate into which the electronic component is inserted; performing surface treatment on the other side of the core substrate opposite to a direction in which the first insulating layer is stacked to improve a surface roughness of at least an exposed surface of the first insulating layer; and stacking a second insulating layer on the other side of the core substrate so as to be bonded to the exposed surface of the first insulating layer of which the surface roughness is improved.

A bonding interface between the first and second insulating layers may be formed at a side section of the electronic component in the cavity.

Mechanical polishing, chemical treatment, or plasma treatment may be performed as the surface treatment.

In the improving of the surface roughness, the surface treatment may be performed on the exposed surface of the first insulating layer, at least a portion of an exposed surface of the electronic component, and at least a portion of the other side of the core substrate.

The inserting of the electronic component into the cavity may include: preparing the core substrate in which the cavity is formed; and adhering an adhesive base onto the other side of the core substrate so that the electronic component adhered onto the adhesive base is inserted into the cavity, and the adhesive base adhered onto the other side of the core substrate may be removed before the performing of the surface treatment.

The inserting of the electronic component into the cavity may include: preparing the core substrate in which the cavity is formed and adhering an adhesive base onto the other side of the core substrate; and inserting the electronic component into the cavity to adhere the electronic component onto the adhesive base, and the adhesive base adhered onto the other side of the core substrate may be removed before the performing of the surface treatment.

The method may further include: forming an inner circuit pattern on at least one of one surface and the other surface of the core substrate before the stacking of the first insulating layer; and forming a via electrically connected to the electronic component while penetrating at least any one of the first and second insulating layers and forming an outer circuit pattern on an outer surface of at least any one of the first and second insulating layers.

According to another exemplary embodiment of the present invention, there is provided an electronic component embedding substrate including: a core substrate having a cavity formed therein; an electronic component inserted into the cavity; a first insulating layer stacked on one side of the core substrate into which the electronic component is inserted; a second insulating layer stacked on the other side of the core substrate opposite to a direction in which the first insulating layer is stacked; and a bonding interface formed by bonding the first and second insulating layers to each other in the cavity and having an improved interface roughness.

The bonding interface between the first and second insulating layers may be formed at a side section of the electronic component in the cavity.

Surface treatment may be performed on at least a portion of surfaces of the electronic component and the core substrate contacting the second insulating layer.

The electronic component embedding substrate may further include a circuit pattern including an inner circuit pattern formed on at least any one of one surface and the other surface of the core substrate, a via pattern electrically connected to the electronic component while penetrating through at least any one of the first and second insulating layers, and an outer circuit pattern formed on an outer surface of at least any one of the first and second insulating layers.

### BRIEF DESCRIPTION OF THE DRAWINGS

FIGS. 1A to 1E are views schematically showing the respective steps of a method for manufacturing an electronic component embedding substrate according to an exemplary embodiment of the present invention;

FIG. 2A is a view schematically showing an electronic component embedding substrate according to the exemplary embodiment of the present invention; and

FIG. 2B is a view schematically showing an electronic component embedding substrate according to another exemplary embodiment of the present invention.

### DESCRIPTION OF THE PREFERRED EMBODIMENTS

Exemplary embodiments of the present invention for accomplishing the above-mentioned objects will be described with reference to the accompanying drawings. In the description, the same reference numerals will be used to describe the same components of which a detailed description will be omitted in order to allow those skilled in the art to understand the present invention.

In the specification, it will be understood that unless a term such as ‘directly’ is not used in a connection, coupling, or disposition relationship between one component and another component, one component may be ‘directly connected to’, ‘directly coupled to’ or ‘directly disposed to’ another element or be connected to, coupled to, or disposed to another element, having the other element intervening therebetween.

Although a singular form is used in the present description, it may include a plural form as long as it is opposite to the concept of the present invention and is not contradictory in view of interpretation or is used as a clearly different meaning. It should be understood that “include”, “have”, “comprise”, “be configured to include”, and the like, used in the present description do not exclude presence or addition of one or more other characteristic, component, or a combination thereof.

The accompanying drawings referred in the present description may be examples for describing exemplary embodiments of the present invention. In the accompanying drawings, a shape, a size, a thickness, and the like, may be exaggerated in order to effectively describe technical characteristics.

Method for Manufacturing Electronic Component Embedding Substrate

A method for manufacturing an electronic component embedding substrate according to a first aspect of the present invention will be described in detail with reference to the accompanying drawings. In the specification, the same reference numerals will be used in order to describe the same components throughout the accompanying drawings.

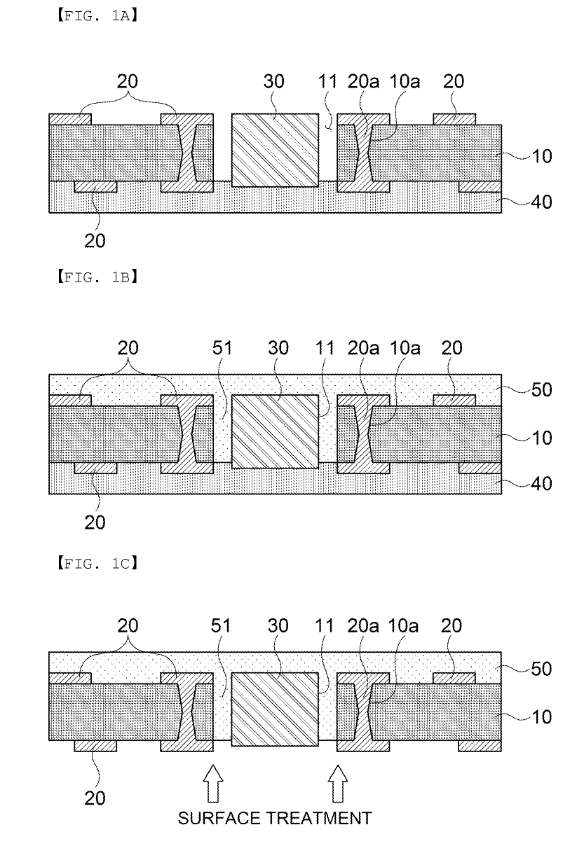

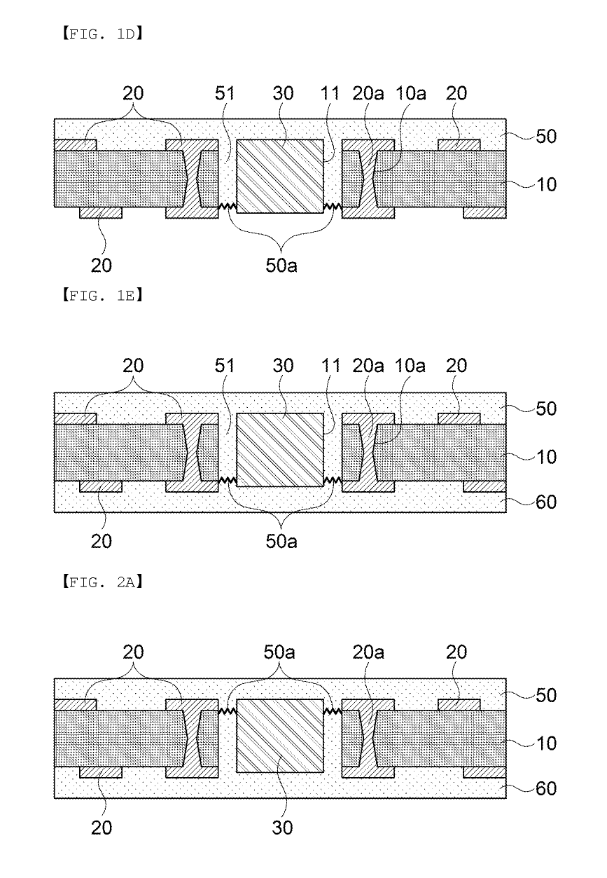

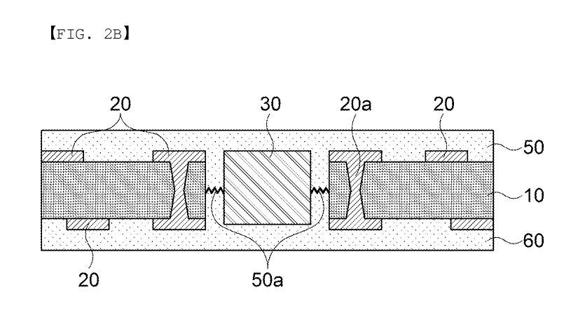

FIGS. 1A to 1E are views schematically showing the respective steps of a method for manufacturing an electronic component embedding substrate according to an exemplary embodiment of the present invention; FIG. 2A is a view schematically showing an electronic component embedding substrate according to the exemplary embodiment of the present invention; and FIG. 2B is a view schematically showing an electronic component embedding substrate according to another exemplary embodiment of the present invention.

Referring to FIGS. 1A to 1E, the method for manufacturing an electronic component embedding substrate according to the exemplary embodiment of the present invention may include inserting an electronic component (See FIG. 1A), stacking a first insulating layer (See FIG. 1B), performing surface treatment (See FIGS. 1C and 1D), and stacking a second insulating layer (See FIG. 1E). Although not shown, according to another exemplary embodiment of the present invention, the method for manufacturing an electronic component embedding substrate may further include forming an outer circuit pattern.

First, referring to FIG. 1A, in the inserting of the electronic component, the electronic component 30 is inserted into a cavity 11 formed in a core substrate 10. In the exemplary embodiment of the present invention, the electronic component 30 may be a passive device, an active device, a semiconductor chip, or the like. For example, the electronic component 30 may be a passive device such as a capacitor, an inductor, or the like. Here, although not shown, the electronic component 30 includes an electrode or a conductive pad disposed thereon and/or therebeneath based on a direction in which it is inserted into the cavity 11. The core substrate 10 may be made of a substrate material that is already known in the art or is to be developed in the future. For example, as a material of the core substrate, a copper clad laminate (CCL), a PPG, an Ajimoto build-up film (ABF), an epoxy resin, a polyimide resin, or the like, may be used.

Further, a metal foil, for example, a copper foil or an inner circuit pattern 20 may be formed on or beneath the core substrate 10. For example, the inner circuit pattern 20 may be formed on at least one of one surface and the other surface of the core substrate 10. For example, referring to FIG. 1A, the core substrate 10 may include a through-via 20a filled in a through-hole 10a and the inner circuit pattern 20 formed on a surface thereof.

For example, in the inserting of the electronic component, a scheme of inserting the electronic component 30 adhered onto an adhesive base 40 into the cavity 11 of the core substrate 10 and a scheme of inserting the electronic component 30 into the cavity 11 of which one side is closed by the adhesive base 40 adhered onto the other side of the core substrate 10 may be used. Here, the other side of the core substrate 10 indicates an opposite side to the side of the core substrate 10 on which the first insulating layer 50 is stacked in the subsequent process. For example, the adhesive base 40 adhered onto the other side of the core substrate 10 may be removed immediately before or before a surface treatment process to be described below. That is, before the surface treatment is performed and after the first insulating layer 50 is stacked on one side of the core substrate 10, the adhesive base 40 adhered onto the other side of the core substrate 10 may be removed.

Although not shown, according to the former, the inserting of the electronic component includes preparing the core substrate 10 in which the cavity 11 is formed and inserting the electronic component 30 adhered onto the adhesive base into the cavity 11. Here, in order to insert the electronic component 30 into the cavity 11, the other side of the core substrate 10 and an upper surface of the adhesive base 40 onto which the electronic component 30 is adhered are adhered to each other so that the electronic component 30 adhered onto the adhesive base 40 is inserted into the cavity 11. For example, the other side of the core substrate is adhered onto the upper surface of the adhesive base 40 or the upper surface of the adhesive base 40 is adhered onto the other side of the core substrate 10. The upper surface of the adhesive base 40 indicates a surface of the adhesive surface onto which the electronic component 30 is adhered. When the other side of the core substrate 10 and the upper surface of the adhesive base 40 having the electronic component 30 adhered thereonto are adhered to each other, the electronic component 30 is inserted toward the other side of the cavity 11 of the core substrate 10.

Although not shown, according to the latter, the inserting of the electronic component includes adhering the adhesive base 40 onto the other side of the core substrate 10 in which the cavity 11 is formed and adhering the electronic component 30 onto the adhesive base 40 in the cavity 11. Here, the cavity 11 is formed in the core substrate 10 and the adhesive base 40 is adhered onto the other side of the core substrate 10. Next, the electronic component 30 is inserted in a direction in which the cavity 11 is opened, such that it is adhered onto the adhesive base 40 forming an internal bottom surface of the cavity 11.

For example, referring to FIG. 1A, in the inserting of the electronic component, in the case of using the adhesive base 40, a height of a surface of the adhesive base 40 in the cavity 11 is adjusted, thereby making it possible to adjust a height of a bonding interface 50 between first and second insulating layers 50 and 60 to be positioned at a surface, a side, and the like, of the electronic component 30 if necessary. For example, the height of the surface of the adhesive base 40 in a space between the electronic component 30 in the cavity 11 and the cavity 11 may be higher than that of a contact surface of the electronic component 30.

Next, referring to FIG. 1B, in the stacking of the first insulating layer, the first insulating layer 50 is stacked on one side of the core substrate 10 into which the electronic component 30 is inserted. A material of the first insulating layer 50 may be a known insulating material used in the substrate. Alternatively, an insulating material for a substrate to be developed in the future may also be used. For example, a PPG, an Ajimoto build-up film, an epoxy resin, a polyimide resin, or the like, may be used.

For example, at the time of stacking the first insulating layer 50, an insulating material in a semi-hardened state is stacked and then compressed, such that it may penetrate into and be filled in a space between the cavity 11 and the electronic component 30. For example, in this case, a semi-hardened degree or a compression strength is adjusted, such that the height of the bonding interface 50a between the first and second insulating layers 50 and 60 depending on stacking of the second insulating layer 60 in the subsequent process may be positioned at a side section of the electronic component 30.

In addition, for example, before the stacking of the first insulating layer, the inner circuit pattern 20 may be formed on at least one of one surface and the other surface of the core substrate 10. For example, in the case, the first insulating layer 50 may be formed on the core substrate 10 on which the inner circuit pattern 20 is formed.

In addition, although not shown, as an example, the method for manufacturing an electronic component embedding substrate according to the exemplary embodiment of the present invention may further include, after the stacking of the first insulating layer 50, forming a via and/or an outer circuit pattern. In this case, although not shown, a via may be electrically connected to the electronic component 30 while penetrating through the first insulating layer 50. Further, although not shown, the outer circuit pattern may be formed on an outer surface of the first insulating layer 50. For example, at the time of stacking the first insulating layer 50, an insulating layer on which a metal foil, for example, a copper foil is stacked may be formed on one side of the core substrate 10. In this case, the copper foil is processed, such that the outer circuit pattern may be formed.

Next, referring to FIGS. 1C and 1D, in the performing of the surface treatment, the surface treatment is performed on the other side of the core substrate 10 opposite to a direction in which the first insulating layer 50 is stacked to improve a surface roughness of at least an exposed surface of the first insulating layer 50. Since the exposed surface of the first insulating layer 50 is bonded to the second insulating layer 60 in the subsequent process, the surface roughness of the exposed surface of the first insulating layer 50 is improved in order to increase bonding force on an interface between the first and second insulating layers 50 and 60. In FIG. 1D, a reference numeral 50a indicates the exposed surface of the first insulating layer 50 subjected to the surface treatment. As a method of improving the surface roughness, existing known methods may be used. Alternatively, surface treatment methods to be developed in the future may also be used. For example, it is preferable that the surface roughness is generally an average surface roughness (Ra=1 μm or less). However, a magnitude of the surface roughness may be adjusted depending on a kind of insulating layer.

For example, as the surface treatment, mechanical polishing, chemical treatment, and/or plasma treatment may be performed. The chemical treatment, the plasma treatment, or the like, is performed on the exposed surface of the first insulating layer 50 to improve the surface roughness, thereby forming an interface 50a of which the surface is activated. Then, in the subsequent process, the second insulating layer 60 is stacked, thereby making it possible to improve the bonding force on the interface between the first and second insulating layers 50 and 60. In addition, in order to improve the surface roughness of the exposed surface of the first insulating layer 50, a mechanical polishing method using a fine powder, or the like, may be used.

For example, referring to FIG. 1C, in the performing of the surface treatment, the surface treatment may be performed on the exposed surface of the first insulating layer 50, at least a portion of an exposed surface of the electronic component 30, and at least a portion of the other side of the core substrate 10. That is, at the time of stacking the second insulating layer 60 in the subsequent process, the surface treatment may be performed so that close adhesion is secured on a bonding surface between the second insulating layer 60 and the exposed surface of the electronic component 30 and/or a bonding surface between the second insulating layer 60 and the other side of the core substrate 10 as well as a bonding interface 50a between the second insulating layer 60 and the first insulating layer 50. For example, the exposed surface of the electronic component 30 may include an electrode and an insulating surface. In this case, the surface treatment may be performed on the electrode of the electronic component 30, the insulating surface of the electronic component 30, or both of the electrode and the insulating surface of the electronic component 30. That is, the surface treatment is performed to also improve a surface roughness of the surface of the electronic component 30, thereby making it possible to improve bonding force between the electronic component 30 and the second insulating layer 60. In addition, the surface treatment may be performed on at least some or all of the inner circuit patterns 20 on the insulating surface of the other side of the core substrate 10, that is, the other surface.

Next, referring to FIG. 1E, in the stacking of the second insulating layer, the second insulating layer 60 is stacked on the other side of the core substrate 10 so as to be bonded to the exposed surface of the first insulating layer 50 having the improved surface roughness. A material of the second insulating layer 60 may be a known insulating material used in the substrate. Alternatively, an insulating material for a substrate to be developed in the future may also be used. As the material of the second insulating layer 60, the same material as that of the first insulating layer 50 or an insulating material different from that of the first insulating layer 50 may be used. As the material of the second insulating layer 60, for example, a PPG, an Ajimoto build-up film, an epoxy resin, a polyimide resin, or the like, may be used.

For example, at the time of stacking the second insulating layer 60, an insulating material in a semi-hardened state is stacked and compressed on the other side of the core substrate 10, such that it may be bonded to the surface-treated exposed surface of the first insulating layer 50 so as to be closely adhered to the surface-treated exposed surface.

Referring to FIGS. 1E, 2A and/or 2B, for example, the bonding interface 50a between the first and second insulating layers 50 and 60 is formed at a side section of the electronic component 30 in the cavity 11. For example, a height around a region of the adhesive base 40 onto which the electronic component 30 is adhered is adjusted or a semi-hardened degree, a compression strength, and the like, of the first insulating layer 50 are adjusted, thereby making it possible to allow the height of the bonding interface 50a between the first and second insulating layers 50 and 60 to be positioned at the side section of the electronic component 30. That is, the height of the bonding interface 50a may be positioned at a central portion of the side of the electronic component 30 as shown in FIG. 2B or be positioned at a position higher than a lower end of the side of the electronic component 30 or a position lower than an upper end of the side of the electronic component 30 as shown in FIG. 1E or 2A. In addition, although not shown, as an example, the method for manufacturing an electronic component embedding substrate according to the exemplary embodiment of the present invention may further include, after the stacking of the second insulating layer 60, forming a via and/or an outer circuit pattern. In this case, although not shown, the via may be electrically connected to the electronic component 30 while penetrating through the second insulating layer 60. Further, although not shown, the outer circuit pattern may be formed on an outer surface of the second insulating layer 60. For example, at the time of stacking the second insulating layer 60, an insulating layer on which a metal foil, for example, a copper foil is stacked may be formed on the other side of the core substrate 10. In this case, the copper foil is processed, such that the outer circuit pattern may be formed.

Electronic component embedding substrate Next, an electronic component embedding substrate according to a second aspect of the present invention will be described in detail with reference to the accompanying drawings. In this case, the method for manufacturing an electronic component embedding substrate according to the first aspect of the present invention described above will be referred. Therefore, an overlapped description will be omitted.

FIG. 1E is a view schematically showing an electronic component embedding substrate according to an exemplary embodiment of the present invention; FIG. 2A is a view schematically showing an electronic component embedding substrate according to another exemplary embodiment of the present invention; and FIG. 2B is a view schematically showing an electronic component embedding substrate according to still another exemplary embodiment of the present invention.

Referring to FIGS. 1e, 2A, and/or 2B, the electronic component embedding substrate according to the exemplary embodiment of the present invention may be configured to include the core substrate 10, the electronic component 30, the first insulating layer 50, the second insulating layer 60, and the bonding interface 50a. Here, the bonding interface 50a is a bonding surface between the first and second insulating layers 50 and 60. In addition, according to the exemplary embodiment of the present invention, the electronic component embedding substrate may further include a circuit pattern. The respective components will be described below in detail.

First referring to FIGS. 1E, 2A, and/or 2B, the core substrate 10 has the cavity 11 formed therein. The core substrate 10 may be made of a substrate material that is already known in the art or is to be developed in the future.

For example, the inner circuit pattern 20 may be formed on at least one of one surface and the other surface of the core substrate 10. For example, referring to FIGS. 1E, 2A, and/or 2B, the core substrate 10 may include the through-via 20a and the inner circuit pattern 20 formed on the surface thereof.

In addition, although not shown, the surface treatment is performed on the surface of the core substrate 10, such that the surface roughness may be improved. Here, the surface of the core substrate 10 on which the surface treatment is performed may be at least a portion of the insulating surface and the inner circuit pattern 20. For example, the surface treatment is performed on the other surface of the core substrate 10 contacting the second insulating layer 60, such that the surface roughness may be improved. In addition, the surface treatment is performed on one surface of the core substrate 10 contacting the first insulating layer 50, such that the surface roughness may be improved.

Next, the electronic component 30 is inserted into the cavity 11 of the core substrate 10. The electronic component 30 may be a passive device such as a capacitor, an inductor, or the like, an active chip, a semiconductor chip, or the like. For example, the electronic component 30 may be a passive device such as a capacitor such as a multilayer ceramic capacitor (MLCC), an inductor such as a multilayer inductor, or the like. Here, the electronic component 30 includes an electrode or a conductive pad disposed thereon and/or therebeneath based on a direction in which it is inserted into the cavity 11.

For example, the surface treatment is performed on the surface of the electronic component 30, such that the surface roughness may be improved. For example, the surface treatment is performed on at least a portion of the surface of the electronic component 30 contacting the second insulating layer 60, such that the surface roughness may be improved. In addition, the surface treatment is also performed on at least a portion of the surface of the electronic component 30 contacting the first insulating layer 50, such that the surface roughness may be improved.

Continuously referring to FIGS. 1E, 2A, and/or 2B, the first insulating layer 50 is stacked on one side of the core substrate 10 into which the electronic component 30 is inserted. For example, a material of the first insulating layer 50 may be a known insulating material used in the substrate. Alternatively, an insulating material for a substrate to be developed in the future may also be used.

Although not shown, the electronic component embedding substrate according to the exemplary embodiment of the present invention may further include a via pattern penetrating through the first insulating layer 50 and/or an outer circuit pattern on the first insulating layer 50. Here, at least a portion of the via pattern is connected to the electronic component 30 while penetrating through the second insulating layer 60. For example, although not shown, in addition to the via connected to the electronic component 30, a via connecting the inner circuit pattern 20 on the core substrate 10 and the outer circuit pattern on the first insulating layer 50 to each other may be provided. Further, the outer circuit pattern may be formed on an outer surface of the first insulating layer 50.

Next, referring to FIGS. 1E, 2A, and/or 2B, the second insulating layer 60 is stacked on the other side of the core substrate 10 opposite to a direction in which the first insulating layer 50 is stacked. A material of the second insulating layer 60 may be a known insulating material used in the substrate. Alternatively, an insulating material for a substrate to be developed in the future may also be used. Here, as the material of the second insulating layer 60, the same material as that of the first insulating layer 50 or an insulating material different from that of the first insulating layer 50 may be used.

Continuously referring to FIGS. 1E, 2A, and/or 2B, the bonding interface 50a is a bonding surface formed by bonding the first and second insulating layers 50 and 60 to each other in the cavity 11. Here, the surface treatment is performed on the bonding surface of the first insulating layer 50, such that an interface roughness of the bonding interface 50a may be improved.

For example, referring to FIGS. 1E, 2A, and/or 2B, the bonding interface 50a may be formed at the side section of the electronic component 30 in the cavity 11. For example, the height of the bonding interface 50a may be positioned at a central portion of the side of the electronic component 30 as shown in FIG. 2B or be positioned at a position higher than a lower end of the side of the electronic component 30 or a position lower than an upper end of the side of the electronic component 30 as shown in FIG. 1E or 2A.

In addition, according to the exemplary embodiment of the present invention, the electronic component embedding substrate may further include a circuit pattern. Here, the circuit pattern may include the inner circuit pattern 20, the via pattern (not shown), and/or the outer circuit pattern (not shown). Referring to FIGS. 1E, 2A, and/or 2B, the inner circuit pattern 20 is formed on at least one of one surface and the other surface of the core substrate 10. Although not shown, the via pattern penetrates through the first and/or second insulating layers 50 and/or 60. Here, the via pattern includes a via electrically connected to the electronic component 30 while penetrating through at least any one of the first and second insulating layers 50 and 60. The via pattern electrically connects the electronic component 30 and/or the inner circuit pattern 20 and the outer circuit pattern to each other. In addition, although not shown, the outer circuit pattern is formed on an outer surface of at least any one of the first and second insulating layers 50 and 60.

According to the exemplary embodiments of the present invention, a first insulating material is primarily stacked, surface treatment is performed on a surface of the first insulating material forming the bonding interface together with a second insulating material to improve a surface roughness, and the second insulating material is secondarily stacked, thereby making it possible to improve bonding force on the bonding interface.

It is obvious that various effects that are not directly stated according to various exemplary embodiments of the present invention may be derived by those skilled in the art from various configurations according to the exemplary embodiments of the present invention.

The accompanying drawings and the above-mentioned exemplary embodiments have been illustratively provided in order to assist in the understanding of those skilled in the art to which the present invention pertains rather than limiting a scope of the present invention. In addition, exemplary embodiments according to a combination of the above-mentioned configurations may be obviously implemented by those skilled in the art. Therefore, various exemplary embodiments of the present invention may be implemented in modified forms without departing from an essential feature of the present invention. In addition, a scope of the present invention should be interpreted according to claims and includes various modifications, alterations, and equivalences made by those skilled in the art.

What is claimed is:

1. A method for manufacturing an electronic component embedding substrate, the method comprising:
inserting an electronic component into a cavity formed in a core substrate;
stacking a first insulating layer on one side of the core substrate into which the electronic component is inserted;
performing surface treatment on the other side of the core substrate opposite to a direction in which the first insulating layer is stacked to improve a surface roughness of at least an exposed surface of the first insulating layer; and
stacking a second insulating layer on the other side of the core substrate so as to be bonded to the exposed surface of the first insulating layer of which the surface roughness is improved.

2. The method according to claim 1, wherein a bonding interface between the first and second insulating layers is formed at a side section of the electronic component in the cavity.

3. The method according to claim 1, wherein mechanical polishing, chemical treatment, or plasma treatment is performed as the surface treatment.

4. The method according to claim 1, wherein in the improving of the surface roughness, the surface treatment is performed on the exposed surface of the first insulating layer, at least a portion of an exposed surface of the electronic component, and at least a portion of the other side of the core substrate.

5. The method according to claim 1, wherein the inserting of the electronic component into the cavity includes: preparing the core substrate in which the cavity is formed; and adhering an adhesive base onto the other side of the core substrate so that the electronic component adhered onto the adhesive base is inserted into the cavity, and
the adhesive base adhered onto the other side of the core substrate is removed before the performing of the surface treatment.

6. The method according to claim 2, wherein the inserting of the electronic component into the cavity includes: preparing the core substrate in which the cavity is formed; and adhering an adhesive base onto the other side of the core substrate so that the electronic component adhered onto the adhesive base is inserted into the cavity, and
the adhesive base adhered onto the other side of the core substrate is removed before the performing of the surface treatment.

7. The method according to claim 4, wherein the inserting of the electronic component into the cavity includes: preparing the core substrate in which the cavity is formed; and adhering an adhesive base onto the other side of the core substrate so that the electronic component adhered onto the adhesive base is inserted into the cavity, and
the adhesive base adhered onto the other side of the core substrate is removed before the performing of the surface treatment.

8. The method according to claim 1, wherein the inserting of the electronic component into the cavity includes: preparing the core substrate in which the cavity is formed and adhering an adhesive base onto the other side of the core substrate; and inserting the electronic component into the cavity to adhere the electronic component onto the adhesive base, and
the adhesive base adhered onto the other side of the core substrate is removed before the performing of the surface treatment.

9. The method according to claim 2, wherein the inserting of the electronic component into the cavity includes: preparing the core substrate in which the cavity is formed and adhering an adhesive base onto the other side of the core substrate; and inserting the electronic component into the cavity to adhere the electronic component onto the adhesive base, and
the adhesive base adhered onto the other side of the core substrate is removed before the performing of the surface treatment.

10. The method according to claim 4, wherein the inserting of the electronic component into the cavity includes: preparing the core substrate in which the cavity is formed and adhering an adhesive base onto the other side of the core substrate; and inserting the electronic component into the cavity to adhere the electronic component onto the adhesive base, and
the adhesive base adhered onto the other side of the core substrate is removed before the performing of the surface treatment.

11. The method according to claim 1, further comprising:
forming an inner circuit pattern on at least one of one surface and the other surface of the core substrate before the stacking of the first insulating layer; and
forming a via electrically connected to the electronic component while penetrating at least any one of the first and second insulating layers and forming an outer circuit pattern on an outer surface of at least any one of the first and second insulating layers.

12. The method according to claim 2, further comprising:
forming an inner circuit pattern on at least one of one surface and the other surface of the core substrate before the stacking of the first insulating layer; and
forming a via electrically connected to the electronic component while penetrating at least any one of the first and second insulating layers and forming an outer circuit pattern on an outer surface of at least any one of the first and second insulating layers.

13. The method according to claim 4, further comprising:
forming an inner circuit pattern on at least one of one surface and the other surface of the core substrate before the stacking of the first insulating layer; and
forming a via electrically connected to the electronic component while penetrating at least any one of the first and second insulating layers and forming an outer circuit pattern on an outer surface of at least any one of the first and second insulating layers.

14. An electronic component embedding substrate comprising:
a core substrate having a cavity formed therein;
an electronic component inserted into the cavity;
a first insulating layer stacked on one side of the core substrate into which the electronic component is inserted;
a second insulating layer stacked on the other side of the core substrate opposite to a direction in which the first insulating layer is stacked; and
a bonding interface formed by bonding the first and second insulating layers to each other in the cavity and having an improved interface roughness.

15. The electronic component embedding substrate according to claim 14, wherein the bonding interface between the first and second insulating layers is formed at a side section of the electronic component in the cavity.

16. The electronic component embedding substrate according to claim 14, wherein surface treatment is performed on at least a portion of surfaces of the electronic component and the core substrate contacting the second insulating layer.

17. The electronic component embedding substrate according to claim 14, further comprising a circuit pattern including an inner circuit pattern formed on at least any one of one surface and the other surface of the core substrate, a via pattern electrically connected to the electronic component while penetrating through at least any one of the first and second insulating layers, and an outer circuit pattern formed on an outer surface of at least any one of the first and second insulating layers.

18. The electronic component embedding substrate according to claim 15, further comprising a circuit pattern including an inner circuit pattern formed on at least any one of one surface and the other surface of the core substrate, a via pattern electrically connected to the electronic component while penetrating through at least any one of the first and second insulating layers, and an outer circuit pattern formed on an outer surface of at least any one of the first and second insulating layers.

19. The electronic component embedding substrate according to claim 16, further comprising a circuit pattern including an inner circuit pattern formed on at least any one of one surface and the other surface of the core substrate, a via pattern electrically connected to the electronic component while penetrating through at least any one of the first and second insulating layers, and an outer circuit pattern formed on an outer surface of at least any one of the first and second insulating layers.
